(19) United States
(12) Patent Application Publication
(10) Pub. No.: US 2026/0205032 A1
(43) Pub. Date: Jul. 16, 2026

(54) METHOD AND APPARATUS FOR ENERGY HARVESTING IN LEADLESS PACEMAKERS

(71) Applicant: NEW JERSEY INSTITUTE OF TECHNOLOGY, Newark, NJ (US)

(72) Inventor: Lin Dong, Warren, NJ (US)

(73) Assignee: NEW JERSEY INSTITUTE OF TECHNOLOGY, Newark, NJ (US)

(21) Appl. No.: 19/449,765

(22) Filed: Jan. 15, 2026

Related U.S. Application Data
(60) Provisional application No. 63/745,518, filed on Jan. 15, 2025.

(51) Int. Cl. H02N 2/18; H02J 50/00; H02N 2/00; H02J 105/46

(52) U.S. Cl. CPC H02N 2/186; H02J 50/001; H02J 50/005; H02N 2/181; H02N 2/22; H02J 2105/46

(57) ABSTRACT

Disclosed is a method and device for energy harvesting designed for implantable medical applications. The device leverages a flexible piezoelectric material, such as polyvinylidene fluoride-trifluoroethylene (P(VDF-TrFE)), and incorporates at least one bistable structural element, such as a molybdenum strip, engineered to undergo snap-through and snap-back transitions during a cardiac cycle. These dynamic transitions produce mechanical deformations of the piezoelectric material, converting biomechanical energy into electrical energy. The apparatus includes electrical contacts, such as gold electrode layers, to capture the electrical energy, which is stored in an energy storage unit for powering implantable devices. To ensure biocompatibility and durability, the device features an encapsulation material, such as polydimethylsiloxane (PDMS). The disclosed method and apparatus provide a self-sustaining energy solution, extending the operational lifespan of implantable medical devices while reducing the need for frequent replacements.

### RELATED APPLICATIONS

This application claims priority to and the benefit of U.S. Provisional Application No. 63/745,518, filed on Jan. 15, 2025, the entire content of which is incorporated by reference herein.

### FIELD OF THE DISCLOSURE

The present disclosure relates to self-powered medical devices. In particular, the present disclosure relates to implantable energy-harvesting devices containing piezoelectric elements for converting biomechanical energy into electrical energy to provide sustained power to the device.

### BACKGROUND

Battery-powered biomedical devices, such as pacemakers and other implantable therapeutics, are vital components in modern healthcare. However, existing devices are significantly limited by their reliance on limited power supply. Leadless, i.e. battery powered pacemakers, advanced cardiac care by eliminating the need for connecting wires and are first implantable without invasive surgery. However, currently available devices remain constrained by battery lifespan, which can last for from 5 to 15 years^{[1-3]}. Once the battery is depleted, device replacement or retrieval can require surgical intervention, introducing risks of complications and imposing substantial financial and physical burdens on patients.

Various alternative methods have been developed to provide power to implantable medical devices; however, there remains a need for approaches that eliminate the need for risk-prone battery replacement procedures without introducing additional risks. For example, devices using longer-lasting nuclear power sources were discontinued due to safety concerns associated with radioactivity exposure. Inductive charging systems were developed to provide an option to recharge, rather than replace device batteries, but require external hardware and inefficient high-frequency operation and can cause patient discomfort. Recent advancements in biomechanical energy harvesting have been applied in the cardiac setting to explore the possibility of converting the heart's mechanical energy into electrical power. However, existing systems typically involve invasive thoracotomies for installation and secure attachment to the heart^{[4-9]}, and are therefore impractical for broad clinical application due to associated surgical risks. There remains a need for improved implantable medical devices with alternative power sources.

### SUMMARY

In accordance with embodiments of the present disclosure, disclosed are methods and devices for energy harvesting involving conversion of biomechanical energy into electrical energy. Exemplary embodiments of energy harvesting devices include implantable energy harvesting devices, for example leadless cardiac pacemaker devices.

In one or more embodiments, an implantable energy harvesting device could include a casing having an energy storage unit in a fixed position therein; and one or more energy harvesting strips comprising: a piezoelectric assembly comprising a flexible piezoelectric material configured to generate electrical energy when deformed; and a bistable structural element configured to undergo a first transition and a second transition responsive to bodily movement, wherein the one or more energy harvesting strips are coupled at a first end to an inner surface of the casing and at a second end to the energy storage unit, the first and second transitions of the bistable structural element causing the piezoelectric material to deform, generating electrical output that is stored in the energy storage unit.

In accordance with embodiments of the present disclosure, the implantable energy harvesting device could include a plurality of energy harvesting strips arranged in one or more integrated arrays, each array comprising two or more strips.

In accordance with embodiments of the present disclosure, the implantable energy harvesting device could include one or more arrays comprising two or more strips connected by a flexible linkage, and configured so that the two or more strips undergo synchronized mechanical oscillations driven by bodily motion.

In accordance with embodiments of the present disclosure, the implantable energy harvesting device could include an energy storage unit enclosure aligned along a center axis of the casing with a space surrounding the enclosure between the enclosure and the casing, the one or more integrated arrays being aligned along the center axis between the enclosure and the inner surface of the casing.

In accordance with embodiments of the present disclosure, the implantable energy harvesting device could include one or more pairs of integrated arrays, each array of the one or more pairs being aligned on the opposite side of the enclosure from the other array of the pair.

In accordance with embodiments of the present disclosure, the implantable energy harvesting device could include a bistable structural element comprising a molybdenum strip having a thickness in a range of from 5 to 15 µm, or from 7 to 13 µm, or from 9 to 11 µm, or any range therebetween.

In accordance with embodiments of the present disclosure, the bistable structural element could include a flexible membrane-based bottom layer configured to flex in response to bodily movement.

In accordance with embodiments of the present disclosure, the flexible membrane-based bottom layer could include a polyethylene terephthalate (PET) film.

In accordance with embodiments of the present disclosure, the flexible membrane-based bottom layer could have a configuration comprising a central core and two or more peripheral elements connected to the central core via shaped linkers configured to provide enhanced flexibility and reliable electrical connectivity under cyclic deformation.

In accordance with embodiments of the present disclosure, the bistable structural element could further include a magnetic film configured to facilitate the first and second transitions.

In accordance with embodiments of the present disclosure, the flexible piezoelectric material could include a polyvinylidene fluoride-trifluoroethylene (P(VDF-TrFE)) film having a thickness in a range of from 10 to 50 µm, or from 15 to 45 µm, or from 20 to 40 µm, or from 25 to 35 µm, or from 28 to 32 µm, or any range therebetween.

In accordance with embodiments of the present disclosure, the P(VDF-TrFE) film could include pores or internal structures configured to enhance electrical output upon deformation of the film.

In accordance with embodiments of the present disclosure, the P(VDF-TrFE) film could be treated using electrical poling and annealing processes to optimize its piezoelectric properties for maximum energy conversion efficiency.

In accordance with embodiments of the present disclosure, the piezoelectric assembly could further include at least one electrode layer in contact with the piezoelectric material, the at least one electrode layer selected from the group of a metal-based electrode layer, a gel-based electrode layer, and a carbon-based electrode layer.

In accordance with embodiments of the present disclosure, the piezoelectric assembly could further include a protective encapsulation layer coating the assembly, wherein the assembly is applied to the bistable structural element.

In accordance with embodiments of the present disclosure, the two or more energy harvesting strips undergo synchronized mechanical oscillations driven by movement of a right ventricle, and the bistable structural element could be configured to undergo one set of first and second transitions per cardiac cycle.

In accordance with embodiments of the present disclosure, movement of the right ventricle could cause a displacement of the casing, and displacement of the casing could cause the two or more strips to undergo synchronized mechanical oscillation.

In accordance with embodiments of the present disclosure, the synchronized mechanical oscillation could have an average amplitude in a range of from 1mm to 12mm, such as from 2 to 10mm, or from 4 to 8 mm, or from 4 to 6 mm, or from 4.5 to 5.5 mm, or any range therebetween.

In accordance with embodiments of the present disclosure, a method for manufacturing an implantable energy harvesting device could include steps of depositing a flexible piezoelectric layer onto a substrate; annealing the flexible piezoelectric layer; applying a bottom gold electrode layer onto a bottom side of the flexible piezoelectric layer; applying a top gold electrode layer onto a top side of the flexible piezoelectric layer to form an electrode configuration; poling the flexible piezoelectric layer; applying a protective encapsulation layer over the flexible piezoelectric layer and electrode configuration to form a flexible piezoelectric assembly; and applying the flexible piezoelectric assembly onto a bistable structural element to form an energy harvesting strip, repeating the process to form a plurality of energy harvesting strips; connecting the plurality of energy harvesting strips with a flexible linkage to form an integrated array; and securing the integrated array within a casing of the implantable energy harvesting device so that each energy harvesting strip of the array is anchored to the casing.

In accordance with embodiments of the present disclosure, a method for harvesting energy from cardiac motion could include positioning an implantable energy harvesting device according to the present disclosure in the right ventricle of the heart of the patient, capturing mechanical energy generated by movement of the right ventricle, the movement causing snap-through and snap-back motions of the bistable structural elements to deform the piezoelectric assembly; converting the mechanical energy into electrical energy, wherein the deformation of the piezoelectric assembly generates an electrical output; and storing the electrical energy in the energy storage unit within the casing to provide sustained power to the device without an external power connection.

Any combination and/or permutation of the embodiments is envisioned. Other objects and features will become apparent from the following detailed description considered in conjunction with the accompanying drawings. It is to be understood, however, that the drawings are designed as an illustration only and not as a definition of the limits of the present disclosure.

### BRIEF DESCRIPTION OF THE DRAWINGS

To assist those of skill in the art in making and using the disclosed method and apparatus for energy harvesting and associated systems and methods, reference is made to the accompanying figures, wherein:

FIG. 1 illustrates a leadless pacemaker in accordance with embodiments of the present disclosure implanted in the bottom of the right ventricle of a heart.

FIG. 2 illustrates bistable energy harvesters integrated within a leadless pacemaker in accordance with embodiments of the present disclosure.

FIG. 3 illustrates a comparison of voltage outputs from porous and non-porous piezoelectric films in accordance with embodiments of the present disclosure.

FIG. 4 illustrates a comparison of charging curves generated from porous and non-porous piezoelectric films in accordance with embodiments of the present disclosure.

FIG. 5 shows a schematic of bistable energy harvesting arrays integrated within a leadless pacemaker in accordance with embodiments of the present disclosure.

FIG. 6A illustrates a first stable state of an energy harvesting element in accordance with embodiments of the present disclosure.

FIG. 6B shows a schematic of an array of energy harvesting elements in a first stable state in accordance with embodiments of the present disclosure.

FIG. 7A illustrates a second stable state of an energy harvesting element in accordance with embodiments of the present disclosure.

FIG. 7B shows a schematic of an array of energy harvesting elements in a second stable state in accordance with embodiments of the present disclosure.

FIG. 8A is a perspective view along the longitudinal axis of an arrangement of energy harvesting elements within a pacemaker casing in accordance with embodiments of the present disclosure.

FIG. 8B is a perspective view along the longitudinal axis of an arrangement of energy harvesting elements within a pacemaker casing in accordance with embodiments of the present disclosure.

FIG. 8C is a perspective view along the longitudinal axis of an arrangement of energy harvesting elements within a pacemaker casing in accordance with embodiments of the present disclosure.

FIG. 9A is a schematic of a multilayer bistable membrane-based energy element with serpentine interconnect configurations in accordance with embodiments of the present disclosure.

FIG. 9B is a schematic of a multilayer bistable membrane-based energy element with gourd-shaped interconnect configurations in accordance with embodiments of the present disclosure.

FIG. 10 is a flowchart showing a method of fabrication bistable energy harvesters in accordance with embodiments of the present disclosure.

### DETAILED DESCRIPTION

Devices and methods of the present disclosure leverage flexible piezoelectric material to construct energy harvesting elements configured to capture, convert, and transmit biomechanical energy. The resulting energy may be transmitted as electric current. In some embodiments, energy may be directed to a battery or other energy storage component of a device that is used to power the device. Devices according to the disclosure may be implantable medical devices, such as, but not limited to, leadless pacemaker devices. Hence, devices of the disclosure may be specifically configured to generate electrical energy from the muscular contractions associated with cardiac function, and therefore provide a robust solution for self-sustaining pacemaker technology.

The present disclosure seeks to enhance the functionality, longevity, and reliability of implantable medical technologies by addressing the limitations associated with traditional battery-dependent devices, especially for reducing the need for invasive battery replacement procedures. Piezoelectric materials are known for their ability to convert mechanical energy into electrical energy. Subjecting such materials, which may include, for example, synthetic or naturally-occurring minerals, ceramics, polymers, and composites thereof, to an external stress such as a mechanical force or electric potential causes a change to the electronic properties of the material. In some materials, this change can cause the material to produce and transmit an electric current, which can be captured, harnessed, or otherwise usefully redirected toward destinations of interest.

The properties of various piezoelectric materials can vary and affect their suitability for use in particular contexts. While conventional piezoelectric ceramics have high piezoelectric coefficients, for example, their inherent rigidity and fragility make them unsuitable for many applications, where even slight stretching may lead to material failure. Piezoelectric nanowires also exhibit inflexibility and brittleness, characterized by high modulus and low fracture strain, making them prone to breakage under minimal deformation. Single-crystal piezoelectric materials, while exhibiting exceptional properties, are inherently brittle and often contain toxic elements. Polymer-based piezoelectric materials offer superior flexibility and durability, with significantly higher fracture strain and lower modulus values than crystalline and mineral-based options. These properties, along with their chemical stability and exceptional biocompatibility, make polymer-based piezoelectrics well-adapted for use in dynamic biological settings, and for seamless integration into well-established systems and devices to install energy-harvesting ability into the same without interfering with primary functions.

As discussed herein, leadless cardiac pacemakers present a promising opportunity for modification with piezoelectric systems, which may be integrated within already-approved products to harness cardiac motion and route the captured energy into the pacemaker battery to create a self-contained, self-powered device with little to no maintenance requirement. Although discussed herein with a focus on the particular context of integration with existing cardiac pacemaker devices, those of skill in the art will understand that the pertinent technologies possess broad applicability in other medical contexts, including in other device types and positionable in other parts of the body to address a wide variety of therapeutic needs different. Thus, embodiments discussed herein should not be considered as limiting the invention, whose teachings can be applied in many other types of biomechanical devices, therapeutic or otherwise, that may benefit from energy harvesting elements type to enable autonomous or self-powered operation.

Energy harvesting elements according to the present disclosure may be arranged in arrays of one or more elements. Energy harvesting elements may be strategically integrated within the architecture of a device to promote activation of the elements without interfering with the operation of the device for therapeutic purposes. In some embodiments directed to a leadless pacemaker comprising electrical components contained in an enclosure such as a casing, one or more energy harvesting elements may be integrated, either individually or as arrays, within non-occupied, unused space within a casing. In exemplary embodiments, energy harvesting elements according to the disclosure are integrated in such space by being connected to one or more other components of the device, including, but not limited to, the casing, a battery, or other functional or structural components.

In a non-limiting example, energy harvesting elements according to the disclosure are integrated in the unused, or “dead” space of a pacemaker model in current clinical use, such as between a battery and an inner surface of a casing or other enclosure. For example, each energy harvesting element can be secured at one edge to an inner surface of a casing and at another edge to a surface of a battery. The positioning and integration of energy harvesting elements may be selected to provide for optimal harvesting of biomechanical energy (i.e., from contraction and/or relaxation of heart muscle or other vicinal tissue) given the shape and structure of the device and its positioning in the body of a patient. In exemplary embodiments, rhythmic contractions of heart muscle can operate to deform the energy harvesting elements, generating an electrical current that is captured and stored to power the pacemaker.

Leadless pacemaker devices in current use often have a battery that occupies approximately 50-60% of the internal volume of the device. For instance, a device may have a cylindrical construction and may have a cylindrical battery aligned along a central longitudinal axis within the device casing, the inner surface of which faces an outer surface of the battery or battery enclosure. The battery may be secured so that it does not move relative to the longitudinal axis. In an exemplary device in which the battery diameter is 3 mm and the casing has an inner diameter of 6.7 mm and a length of 10 mm along the longitudinal axis, the remaining space within the casing can accommodate integration of energy harvesting elements (which may be alternatingly referred to herein as “strips” or “beams”) with approximate dimensions of 0.5 mm x 1.85 mm and thickness of 60 µm.

Materials and methods included in exemplary embodiments of the present disclosure are described herein. While specific materials and techniques are discussed with respect to certain embodiments, it is understood that other suitable materials and methods may be used, and similar quantities, sizes, or measurements may be substituted in accordance with the present disclosure.

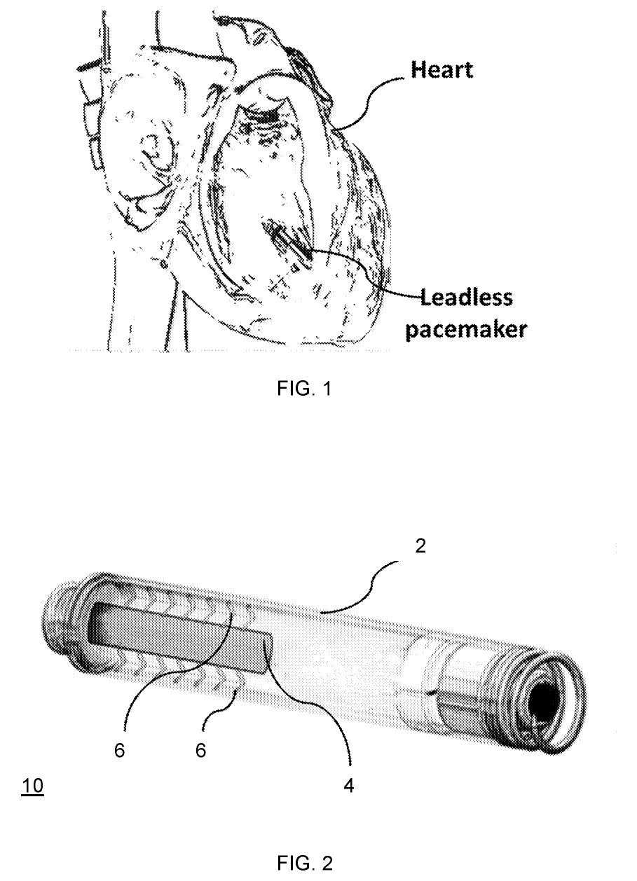

FIG. 1 illustrates one embodiment of an implantable energy harvesting device, such as a leadless pacemaker 10 as shown in FIG. 2, implanted in the bottom of the right ventricle of a heart. Devices of the present disclosure are configured to move in sync with the heart's natural motion during each cardiac cycle. As the heart contracts and relaxes, the pacemaker follows the rhythmic movements of the heart wall, enabling it to capture the mechanical energy generated. When the battery 4 is positioned at the end of the device that is distal from where the device is attached to the ventricle, energy harvesting elements 6 can be secured to the pacemaker casing 2 and can be positioned to provide for both safety and efficient space utilization. As the device moves in tandem with ventricular rhythm during the cardiac cycle, the energy harvester undergoes complex motions that mirror the intricate dynamics of the heart. This motion activates the energy harvesting mechanism within the pacemaker, converting the biomechanical energy into electrical power that can be used to sustain the pacemaker’s function without the need for external power sources or frequent battery replacements. The pacemaker's ability to move with the heart ensures continuous and reliable energy generation, contributing to the pacemaker’s long-term functionality.

In exemplary embodiments, an energy harvesting device of the present disclosure includes one or more energy harvesting elements, or strips, 6 each comprising a piezoelectric polymer film, a bistable strip, one or more electrodes, and optionally one or more encapsulating layers. In one or more embodiments, the flexible piezoelectric materials can include polyvinylidene fluoride-trifluoroethylene (P(VDF-TrFE)). Other suitable flexible piezoelectric materials include, but are not limited to, such as lead zirconate titanate (PZT), aluminum nitride (AlN), and polyvinylidene fluoride (PVDF). In one or more embodiments the bistable strip can be made from molybdenum. Other suitable bistable strip materials include, but are not limited to, stainless steel, shape memory alloys, and fluidic elastomers. In one or more embodiments, the electrode layers are made from gold. Other embodiments may use different electrode layers, including, but not limited to, other metallic electrodes (e.g., silver, copper); gel-based electrodes (e.g., silver/silver chloride (Ag/AgCl)); and carbon-based electrodes (e.g., carbon nanotubes (CNTs). In one or more embodiments, the encapsulating layers are made from polydimethylsiloxane (PDMS). Other materials suitable for use in encapsulating layers include, but are not limited to polyurethane, silicone-based polymers, or other biocompatible materials. In certain embodiments, an assembled energy harvesting element 6 may have a total thickness of from 30 µm to 120 µm, comprising a bistable strip, a piezoelectric polymer film, gold electrode layers, and encapsulating polydimethylsiloxane (PDMS) layers. In exemplary embodiments, an assembled energy harvesting element 6 may have a total thickness in a range of from 35 µm to 110 µm, or from 40 µm to 100 µm, or from 45 µm to 90 µm, or from 48 µm to 80 µm, or from 50 µm to 75 µm, or from 52 µm to 70 µm, or from 54 µm to 66 µm, or from 56 µm to 64 µm, or from 58 µm to 62 µm, or any range therebetween.

In exemplary embodiments, energy harvesting elements 6 of the present disclosure leverage a direct integration of piezoelectric polymer films with bistable structural elements to improve space-efficiency and energy output. In a particular non-limiting embodiment, an energy harvesting element can be assembled by subjecting a 30 µm-thick layer of piezoelectric polymer P(VDF-TrFE), sized at 4 mm x 6 mm, to annealing at 135 °C, followed by electrical poling in which an electric field of 80 V/µm is applied. Two conductive layers, or electrodes, are applied onto both surfaces of piezoelectric film to create an energy harvesting element. In some embodiments, one or more electrode layers can be applied to surfaces of the piezoelectric film by sputter-coating. In some embodiments, the electrode layer can be a 10 nm-thick gold film, Additionally, a 10 µm-thick layer of polydimethylsiloxane (PDMS) is applied to encapsulate the energy harvester, thereby securing it in place.

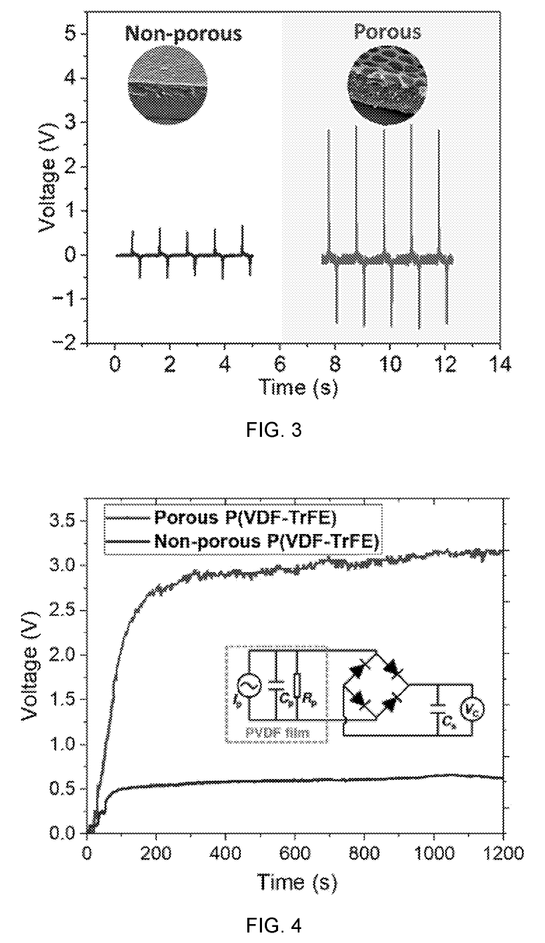

P(VDF-TrFE) film may be configured with either porous or non-porous internal structures, allowing customization to enhance performance for various piezoelectric energy harvesting applications. Piezoelectric properties of P(VDF-TrFE) film subjected to mechanical input were evaluated at 1 Hz input rate simulating a pulse of 60 beats per minute, with a displacement amplitude of up to 5 mm to approximate the motion of the right ventricular free wall. Electrical output from the energy harvester according to the present disclosure was monitored continuously. Energy generation (FIG. 3) and charging capabilities (FIG. 4) of both porous and non-porous P(VDF-TrFE) films were assessed.

FIG. 3 presents a comparison between the voltage outputs generated by porous and non-porous P(VDF-TrFE) films under similar excitation conditions. The porous configuration demonstrated a significantly enhanced electrical output, achieving 3 V within approximately 375 seconds, and effective power output of 0.6 μW across a 50 μF capacitor. The porous P(VDF-TrFE) films exhibit superior piezoelectric properties, yielding significantly higher voltage outputs, thereby confirming their enhanced efficiency for biomedical energy harvesting applications. Further, the porous structure was observed to improve flexibility, durability, and responsiveness, making it highly suited for use in dynamic, long-term medical applications.

FIG. 4 displays the charging curves for a 50 μF capacitor connected to the porous P(VDF-TrFE) film, showing steady charge accumulation over cardiac cycles. This data underscores the ability of the energy harvesting device of the present disclosure to continuously capture and store energy, supporting extended pacemaker operation. This configuration is expected to scale efficiently with the addition of further bistable energy harvesters, thereby enhancing the overall power yield of the present energy harvesting device and contributing to extended operational lifespans.

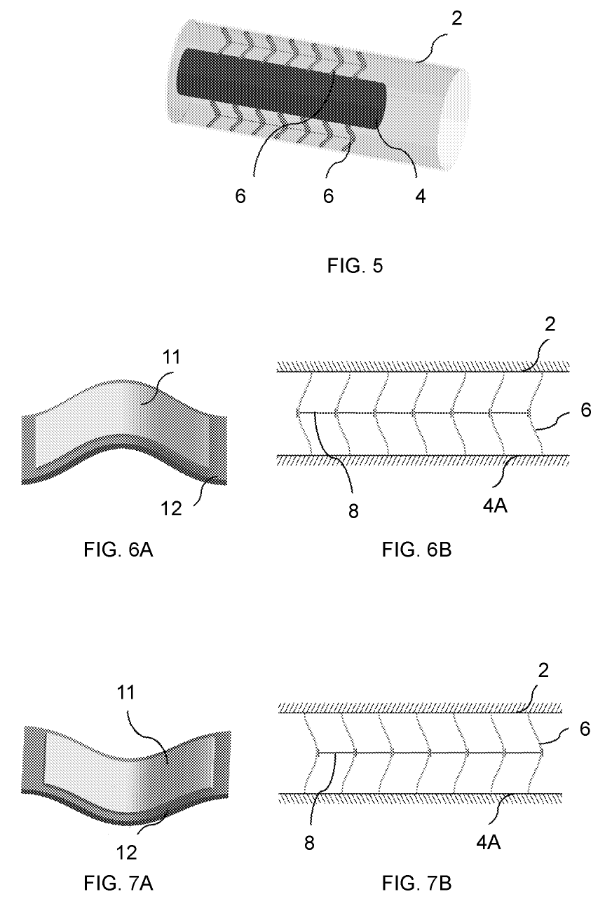

FIG. 5 shows a schematic illustration of one embodiment of an implantable energy harvesting device 10 of the present disclosure. The embodiment of FIG. 5 includes energy harvesting elements 6 integrated into the leadless pacemaker as two arrays of seven elements positioned within the available space in the pacemaker casing 2. While fourteen energy harvesting elements 6 are shown, it will be understood that the number of elements per array and the number of arrays could vary. In this embodiment, each array, and each element 6 therein, is secured in the device with one end affixed to an inner surface of the device casing 2 and the other end to an outer surface 4A of a battery or battery enclosure 4. This placement is chosen for the energy harvesting elements 6 to occupy otherwise unused space within a conventional leadless pacemaker, thereby maintaining a compact design.

In some embodiments, energy harvesting elements of the present disclosure are composed of a piezoelectric polymer material 11, such as P(VDF-TrFE), directly integrated with bistable structural elements 12, such as molybdenum strips, as illustrated in FIG. 6A. This construction is another space-saving feature, wherein energy harvesting components are consolidated to allow a greater number to fit within a single device and to avoid interference with other components essential to the pacemaker’s function in maintaining regular cardiac rhythm. The mechanism of the elements for harvesting biomechanical energy is activated by the bodily movements of the cardiac cycle. The material and dimensions of the bistable structural elements 12 are configured so that the element will naturally tend toward either a first stable position or a second stable position. In non-limiting embodiments of the present invention, the first and second positions have approximately equal stability. During a diastolic phase of the heartbeat of a patient, the apex impulse of the heart may momentarily destabilize the bistable structural element 12, causing it to transition between a first stable state and a second stable state via a snap-through buckling event. This transition can excite localized oscillations of the bistable structural element at a frequency greater than the frequency of the heartbeat. This oscillatory motion causes attached the piezoelectric film 11 to deform, generating electrical energy. In the systolic phase, a snap-back event occurs as the bistable structural element 12 reverts to its original position, maintaining a continuous energy generation cycle. By alternating between these two stable states, the energy harvesting system of the present disclosure effectively converts each heartbeat into electrical power.

In one or more embodiments of the present disclosure, P(VDF-TrFE) film is applied directly onto bistable structural elements 12 composed of 10 µm-thick molybdenum, with one or more electrode layers applied directly to the piezoelectric film. In particular non-limiting embodiments, the electrodes may be 10 nm-thick gold electrode layers. The resulting energy harvesting strips 6 can transition from a first stable state as shown in FIG. 6A to a second stable state as shown in FIG. 7A during in a snap-through event, driven by the transition of the bistable structural element in response to a diastolic phase. During a cardiac systolic phase, a snap-back response occurs, facilitating the transition from the second stable state back to the first stable state. Inducing the bistable structural element 12, and therefore the energy harvesting element 6 comprising a piezoelectric material 11, to alternate between these two stable states causes the piezoelectric material 11 to generate electrical energy which can then be collected and stored. The dynamic characteristics of the snap-through response, along with the potential for their modulation (e.g., by adjusting structural geometry, material properties, or boundary conditions), presents significant opportunities to advance biomedical devices.

In one or more embodiments, individual energy harvesting strips 6 can be connected through a flexible linkage 8 to form an integrated energy harvesting array as shown in FIG. 6B and FIG. 7B. Although the Figures show arrays containing seven strips, the scalable design of the present disclosure allows construction of arrays containing any number of strips. For example, an array may contain 2 strips, or 3 strips, or 4 strips, or 5 strips, or 6 strips, or 7 strips, or 8 strips, or 9 strips, or 10 strips, or 12 strips, or 24 strips, or 48 strips, or any number therebetween. In some embodiments the flexible linkage is a 3D-printed linkage, although it will also be understood by those of skill in the art that other suitable means for connecting strips 6 in an array could be used.

One or more such energy harvesting arrays can be secured within a device casing 2. In one or more embodiments, each strip of the array, and therefore the array as a whole, can be anchored at one end to an inner surface of the device casing 2 and at another end to an outer surface 4A of battery enclosure 4, ensuring secure positioning while enabling the strips 6 to undergo synchronized mechanical oscillations driven by cardiac motion, which generates electrical power to supply the present pacemaker. In one or more embodiments, the flexible linkage 8 connecting individual energy harvesting strips 6 to form an array can encourage synchronized oscillation of the strips 6 therein; for example, oscillation between the first stable conformation shown in FIG. 6B and the second stable conformation shown in FIG. 7B. Synchronized operation of the energy harvesting strips 6 in such fashion promotes continuous, steady power generation during both the heart’s rhythmic and arrhythmic beats. Electrical output generated by each energy harvesting strip 6 may be routed through conductive interconnects connected to an electrical network, such as, but not limited to a series, parallel, or hybrid configuration, en route to delivery to the device battery 4 for energy storage. Harvested energy can thus be transmitted from the energy harvesting strips 6 to the battery 4 where it can be stored and/or used to power the device’s function, such as a pacemaking function, significantly reducing or eliminating the need for battery replacement.

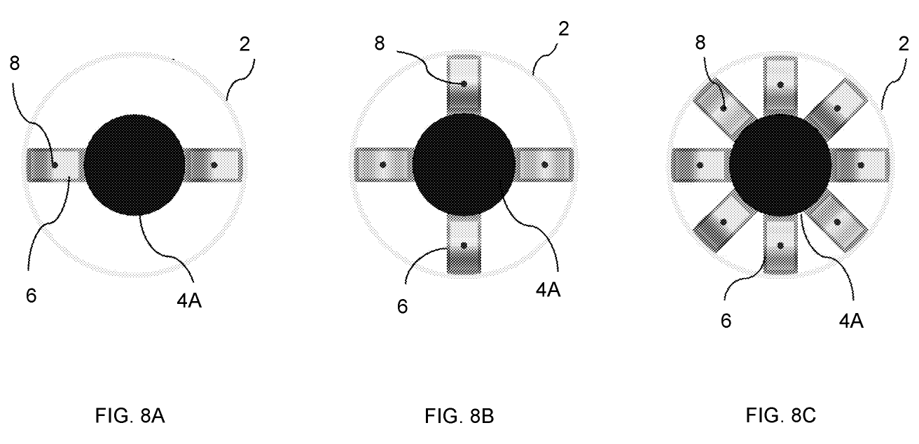

The linkage of multiple energy harvesting elements 6 into a connected array, as well as the integration of arrays into an implantable medical device, is scalable in accordance with the disclosure. For example, as shown in the schematic illustrations of non-limiting embodiments in FIGS. 8A-C, showing perspective views along the longitudinal axis of an exemplary integrated device 10, multiple elements 6 or arrays thereof can be integrated into a single device as space permits. In the embodiment shown in FIG. 8A, two energy harvesting arrays, each containing seven energy harvesting elements, or strips 6, are integrated resulting in 14 total energy harvesting strips, in the device. Additional energy harvesting arrays can be incorporated for configurations including, for example, four or eight arrays, resulting in a total of 28 (FIG. 8B) or 56 (FIG. 8C) total energy harvesting strips 6 in a device 10, respectively. It will be understood by those of skill in the art that different numbers of strips per array, and arrays per device, can be used. This scalability offers the opportunity to significantly enhance energy generation, as each additional array directly contributes to increased energy output, improving the overall efficiency and effectiveness of the device. This feature further prepares devices of the present disclosure for long-term, self-powered operation, wherein scaled configurations are able to meet higher power demands and/or to further extend pacemaker lifespan.

In preliminary evaluations of energy harvesting devices of the present disclosure, P(VDF-TrFE) piezoelectric films, including P(VDF-TrFE) with porous internal structure, generated an electrical output of approximately 3 V within 375 seconds under mechanical excitation replicating heart motion at 1 Hz (60 beats per minute), with a displacement amplitude up to 5 mm. The power output reached 0.6 μW measured across a 50 μF capacitor.

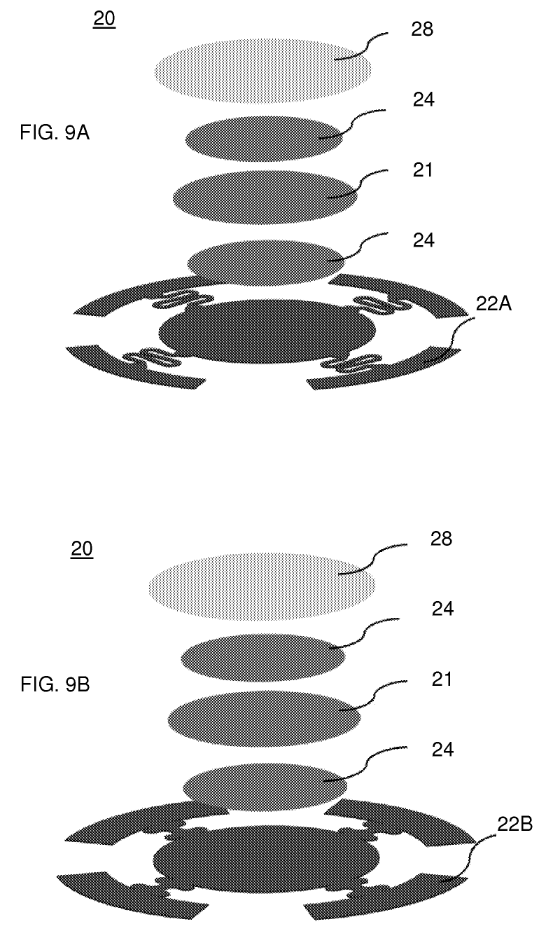

FIGS. 9A-B illustrate embodiments of energy harvesting elements, or strips, 20, comprising particular embodiments of a bistable polymer layer having serpentine interconnect configurations 22A (FIG. 9A) and gourd-shaped interconnect configurations 22B (FIG. 9B). These polymer layers may comprise a polymeric film, such as, but not limited to, polyethylene terephthalate (PET). The embodiments shown in the figures are configured with various interconnect geometries to provide enhanced flexibility, and thus capacity for greater deformation of piezoelectric layer 21 and therefore piezoelectric energy conversion. In these and other embodiments, the middle layers of the energy harvesting strip may include piezoelectric polymer 21 coated, or surrounded, with electrode layer(s) 24. As shown in FIGS. 9A-B, embodiments of energy harvesting elements may further comprise a top layer comprising a magnetic film 28. Magnetic films or similar elements 28 may be included to reduce the energy barrier for the structural transitions described above and facilitate actuation of bistable polymer layer 22A / 22B using magnetic forces.

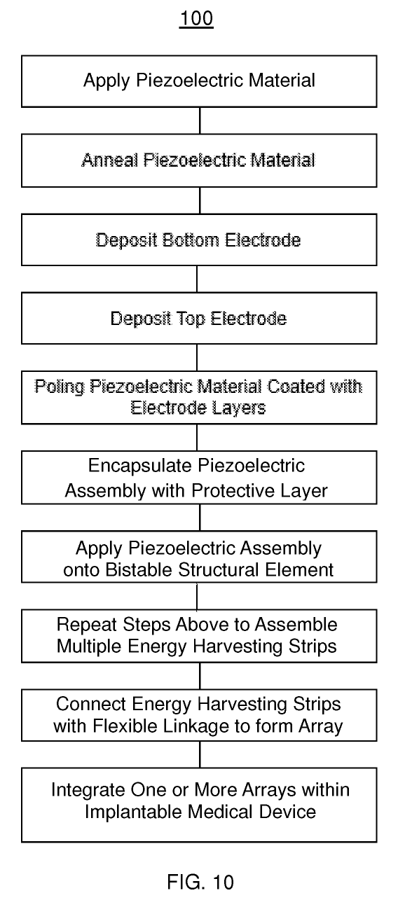

FIG. 10 outlines an exemplary embodiment of a process 100 for assembling energy harvesting elements and implantable energy harvesting devices in accord with the present disclosure. Assembly begins with the deposition of a layer of piezoelectric material of P(VDF-TrFE) onto a suitable substrate, such as a glass slide. The piezoelectric material is then annealed to enhance its crystallinity and optimize its piezoelectric properties. Following the annealing process, a bottom gold electrode layer is sputter coated onto the piezoelectric material to establish electrical contact. A top gold electrode layer is subsequently applied to complete the electrode configuration, allowing the piezoelectric material to function effectively for energy harvesting. After the electrode layers are applied, the piezoelectric material undergoes a poling process to align the dipoles and activate its piezoelectric properties. To protect the piezoelectric material and ensure its durability, an encapsulation layer, such as polydimethylsiloxane (PDMS), is applied to ensure durability and stability of the energy harvester. The fabrication process, along with proper encapsulation, guarantees that the energy harvester withstands the cardiac environment while maintaining efficient energy conversion over extended periods. Next, the piezoelectric assembly is applied to a bistable structural element, which in some embodiments can be a molybdenum strip. This process can be repeated to create multiple energy harvesting strips, each capable of converting biomechanical energy into electrical energy. In one or more embodiments, individual energy harvesting strips can be connected with a flexible linkage to form an integrated energy harvesting array, and one or more arrays can be integrated within a casing of an implantable medical device.

While exemplary embodiments have been described herein, it is expressly noted that these embodiments should not be construed as limiting, but rather that additions and modifications to what is expressly described herein also are included within the scope of the invention. Moreover, it is to be understood that the features of the various embodiments described herein are not mutually exclusive and can exist in various combinations and permutations, even if such combinations or permutations are not made express herein, without departing from the spirit and scope of the invention.

### References

1. J. Dean and N. Sulke, "Pacemaker battery scandal," BMJ, vol. 352, p. i228, 2016.

2. S. Manolis, T. Maounis, S. Koulouris, and V. Vassilikos, "“Real life” longevity of implantable cardioverter-defibrillator devices," Clinical Cardiology, vol. 40, pp. 759-764, 2017.

3. S. Richter, M. Döring, M. Ebert, K. Bode, A. Müssigbrodt, P. Sommer, et al., "Battery Malfunction of a Leadless Cardiac Pacemaker," Circulation, vol. 137, pp. 2408-2410, 2018.

4. Dagdeviren, B. D. Yang, Y. Su, P. L. Tran, P. Joe, E. Anderson, et al., "Conformal piezoelectric energy harvesting and storage from motions of the heart, lung, and diaphragm," Proceedings of the National Academy of Sciences, vol. 111, p. 1927, 2014.

5. N. Li, Z. Yi, Y. Ma, F. Xie, Y. Huang, Y. Tian, et al., "Direct Powering a Real Cardiac Pacemaker by Natural Energy of a Heartbeat," ACS Nano, vol. 13, pp. 2822-2830, 2019.

6. Lu, Y. Chen, D. Ou, H. Chen, L. Diao, W. Zhang, et al., "Ultra-flexible Piezoelectric Devices Integrated with Heart to Harvest the Biomechanical Energy," Scientific Reports, vol. 5, p. 16065, 2015.

7. H. Ouyang, Z. Liu, N. Li, B. Shi, Y. Zou, F. Xie, et al., "Symbiotic cardiac pacemaker," Nature Communications, vol. 10, p. 1821, 2019.

8. Q. Zheng, H. Zhang, B. Shi, X. Xue, Z. Liu, Y. Jin, et al., "In Vivo Self-Powered Wireless Cardiac Monitoring via Implantable Triboelectric Nanogenerator," ACS Nano, vol. 10, pp. 6510-6518, 2016.

9. Z. Yi, F. Xie, Y. Tian, N. Li, X. Dong, Y. Ma, et al., "A Battery- and Leadless Heart-Worn Pacemaker Strategy," Advanced Functional Materials, vol. 30, p. 2000477, 2020.

What is claimed is:

1. An implantable energy harvesting device, comprising:
a casing having an energy storage unit in a fixed position therein; and
one or more energy harvesting strips comprising:
a piezoelectric assembly comprising a flexible piezoelectric material configured to generate electrical energy when deformed; and
a bistable structural element configured to undergo a first transition and a second transition responsive to bodily movement,
wherein the one or more energy harvesting strips are coupled at a first end to an inner surface of the casing and at a second end to the energy storage unit, the first and second transitions of the bistable structural element causing the flexible piezoelectric material to deform, generating electrical output that is stored in the energy storage unit.

2. The implantable energy harvesting device of claim 1, wherein the one or more energy harvesting strips comprises a plurality of energy harvesting strips arranged in one or more integrated arrays, each array comprising two or more strips.

3. The implantable energy harvesting device of claim 2, each array comprising two or more strips connected by a flexible linkage, and configured so that the two or more strips undergo synchronized mechanical oscillations driven by bodily motion.

4. The implantable energy harvesting device of claim 2, wherein the energy storage unit comprises an enclosure aligned along a center axis of the casing with a space surrounding the enclosure between the enclosure and the casing, the one or more integrated arrays being aligned along the center axis between the enclosure and the inner surface of the casing.

5. The implantable energy harvesting device of claim 4, wherein the one or more integrated arrays comprises one or more pairs of integrated arrays, each array of the one or more pairs being aligned on the opposite side of the enclosure from the other array of the pair.

6. The implantable energy harvesting device of claim 1, the bistable structural element comprising a molybdenum strip having a thickness in a range of from 5-15 µm.

7. The implantable energy harvesting device of claim 1, the bistable structural element comprising a flexible membrane-based bottom layer configured to flex in response to bodily movement.

8. The implantable energy harvesting device of claim 7, the flexible membrane-based bottom layer comprising a polyethylene terephthalate (PET) film.

9. The implantable energy harvesting device of claim 7, wherein the flexible membrane-based bottom layer has a configuration comprising a central core and two or more peripheral elements connected to the central core via shaped linkers configured to provide enhanced flexibility and reliable electrical connectivity under cyclic deformation.

10. The implantable energy harvesting device of claim 7, the bistable structural element further comprising a magnetic film configured to facilitate the first and second transitions.

11. The implantable energy harvesting device of claim 1, the flexible piezoelectric material comprising a polyvinylidene fluoride-trifluoroethylene (P(VDF-TrFE)) film having a thickness in a range of from 10 to 50 µm.

12. The implantable energy harvesting device of claim 11, wherein the P(VDF-TrFE) film comprises pores or internal structures configured to enhance electrical output upon deformation of the film.

13. The implantable energy harvesting device of claim 11, wherein the P(VDF-TrFE) film is treated using electrical poling and annealing processes to optimize its piezoelectric properties for maximum energy conversion efficiency.

14. The implantable energy harvesting device of claim 11, the piezoelectric assembly further comprising at least one electrode layer in contact with the flexible piezoelectric material, the at least one electrode layer selected from a metal-based electrode layer, a gel-based electrode layer, and a carbon-based electrode layer.

15. The implantable energy harvesting device of claim 14, the piezoelectric assembly further comprising a protective encapsulation layer, wherein the piezoelectric assembly is applied to the bistable structural element.

16. The implantable energy harvesting device of claim 3, wherein the bodily motion is movement of a right ventricle, and the synchronized mechanical oscillations comprise one set of first and second transitions per cardiac cycle.

17. The implantable energy harvesting device of claim 16, wherein movement of the right ventricle causes a displacement of the casing, and displacement of the casing causes the synchronized mechanical oscillations.

18. The implantable energy harvesting device of claim 16, wherein the synchronized mechanical oscillations have an average amplitude in a range of from 1mm to 12mm.

19. A method of manufacturing an implantable energy harvesting device, the method comprising a process of:
depositing a flexible piezoelectric layer onto a substrate;
annealing the flexible piezoelectric layer;
applying a bottom gold electrode layer onto a bottom side of the flexible piezoelectric layer;
applying a top gold electrode layer onto a top side of the flexible piezoelectric layer to form an electrode configuration;
poling the flexible piezoelectric layer;
applying a protective encapsulation layer over the flexible piezoelectric layer and electrode configuration to form a flexible piezoelectric assembly; and
applying the flexible piezoelectric assembly to a bistable structural element to form an energy harvesting strip,
repeating the process to form a plurality of energy harvesting strips;
connecting the plurality of energy harvesting strips with a flexible linkage to form an integrated array; and
securing the integrated array within a casing of the implantable energy harvesting device so that each energy harvesting strip of the integrated array is anchored to the casing.

20. A method for harvesting energy from cardiac motion comprising:
positioning the implantable energy harvesting device of claim 1 in a right ventricle of a heart of a patient,
capturing mechanical energy generated by movement of the right ventricle, the movement causing snap-through and snap-back motions of the bistable structural elements to deform the piezoelectric assembly;
converting the mechanical energy into electrical energy, wherein deformation of the piezoelectric assembly generates an electrical output; and
storing the electrical energy in the energy storage unit within the casing to provide sustained power to the device without an external power connection.
